(19) United States
(12) Patent Application Publication
(10) Pub. No.: US 2007/0267680 A1
(43) Pub. Date: Nov. 22, 2007

(54) SEMICONDUCTOR INTEGRATED CIRCUIT DEVICE

(75) Inventors: Yukinori Uchino, Yokohama-shi (JP); Muneaki Maeno, Yokohama-shi (JP); Yoichi Takegawa, Yokohama-shi (JP); Hisato Oyamatsu, Yokohama-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/749,274

(22) Filed: May 16, 2007

(30) Foreign Application Priority Data
May 17, 2006 (JP) 2006-138019

(51) Int. Cl. H01L 29/788

(52) U.S. Cl. 257/315

(57) ABSTRACT

A semiconductor integrated circuit device contains a CMOS circuit that includes a plurality of N-channel transistors and a plurality of P-channel transistors. The plurality of N-channel transistors is provided with device isolation by one of a gate isolation structure and a shallow trench isolation structure. The plurality of P-channel transistors are provided with device isolation by the other of the gate isolation structure and the shallow trench isolation structure.

### CROSS-REFERENCE TO RELATED APPLICATIONS

This application is based upon and claims the benefit of priority from prior Japanese Patent Application No. 2006-138019, filed May 17, 2006, the entire contents of which are incorporated herein by reference.

### BACKGROUND OF THE INVENTION

1. Field of the Invention

The present invention relates to a semiconductor integrated circuit device containing a CMOS circuit, and specifically to a semiconductor integrated circuit device arranged to control the performance of transistors by use of stress due to shallow trench isolation (STI).

2. Description of the Related Art

In recent years, a strained silicon technique has been in practical use for semiconductor techniques from a 90-nm generation, such that silicon crystal lattices are stretched to increase the mobility of electrons in transistors. According to a typical strained silicon technique, a silicon layer is formed on a substance layer having a larger lattice constant, so the atoms of the silicon layer are arrayed in accordance with the lattice intervals of the substance layer having a larger lattice constant. Consequently, internal strains are caused in the silicon layer, and transistors are thereby improved in characteristic. For example, in the case of a P-channel transistor, where STI is present in a direction perpendicular to the gate electrode, compression stress acts inside the transistor, and the transistor is thereby improved in performance. On the other hand, in the case of an N-channel transistor, where no STI is present in a direction perpendicular to the gate electrode, the channel region is free from compression stress applied from the STI, and the transistor is thereby prevented from suffering degraded performance.

Jpn. Pat. Appln. KOKAI Publication No. 2003-203989 discloses a standard cell array and a gate array, in each of which P-channel transistors are isolated by STI and N-channel transistors are isolated by STI. According to the standard cell array and gate array having this structure, it is difficult to efficiently improve the transistors in performance by use of STI stress.

### BRIEF SUMMARY OF THE INVENTION

According to a first aspect of the present invention, there is provided a semiconductor integrated circuit device comprising a CMOS circuit that includes a plurality of N-channel transistors provided with device isolation by one of a gate isolation structure and a shallow trench isolation structure, and a plurality of P-channel transistors provided with device isolation by the other of the gate isolation structure and the shallow trench isolation structure.

According to a second aspect of the present invention, there is provided a semiconductor integrated circuit device comprising: a first region that includes a plurality of first channel transistors provided with device isolation by a shallow trench isolation structure; and a second region that includes a plurality of second channel transistors provided with device isolation by a gate isolation structure.

### BRIEF DESCRIPTION OF THE SEVERAL VIEWS OF THE DRAWING

FIG. 1 is a plan view showing the pattern layout of a semiconductor integrated circuit device according to a first embodiment;

FIG. 2 is a plan view showing the pattern layout of a gate array according to an example of the first embodiment;

FIG. 3 is a plan view showing the pattern layout of a device where the gate array shown in FIG. 2 is applied to a two-input AND gate circuit and a two-input OR gate circuit, which are of the CMOS type;

FIG. 4 is a plan view showing the pattern layout of a semiconductor integrated circuit device according to a first modification of the first embodiment;

FIG. 5 is a plan view showing the pattern layout of a semiconductor integrated circuit device according to a second modification of the first embodiment;

FIG. 6 is a plan view showing the pattern layout of a semiconductor integrated circuit device according to a second embodiment; and

FIG. 7 is a plan view showing the pattern layout of a semiconductor integrated circuit device according to a fourth embodiment.

### DETAILED DESCRIPTION OF THE INVENTION

Embodiments of the present invention will now be described with reference to the accompanying drawings. In the following description, the constituent elements having substantially the same function and arrangement are denoted by the same reference numerals through all the drawings.

At first, an explanation will be given of an outline of the present invention. A semiconductor integrated circuit device according to the present invention includes a plurality of N-channel transistors and a plurality of P-channel transistors formed therein. The transistors of one of the N-channel type and the P-channel type are provided with gate isolation structures. The transistors of the other of the N-channel type and the P-channel type are provided with shallow trench isolation (STI) structures.

With this arrangement, the transistors of one channel type receive no STI stress, while the transistors of the other channel type receive STI stress to cause the effect of changing the performance thereof, i.e., a strained silicon effect.

More specifically, where the N-channel transistors are provided with the gate isolation structures, the interiors of the transistors are free from stress in a compression direction applied from STI, and the transistors are thereby prevented from suffering degraded performance. Further, where the P-channel transistors are provided with the STI isolation structures, the interiors of the transistors receive stress in a compression direction applied from STI, and the transistors are thereby improved in performance. In other words, the performance of both of the P-channel and N-channel transistors can be controlled by use of STI stress, so that the performance of both of them is efficiently improved.

It should be noted that, depending on the manufacturing process, an arrangement opposite to that described above may be effective to improve transistors in performance and/or to prevent transistors from suffering degraded performance. In this case, N-channel transistors are provided with STI structures, while P-channel transistors are provided with gate isolation structures.

Further, where P-channel transistors are provided with gate isolation structures, while N-channel transistors are provided with STI structures, the delay characteristic of transistors can be controlled to increase the delay. In this case, a delay cell for adjusting clock skew can be formed to have a delay characteristic with a greater delay, so the size of the delay cell can be smaller.

### First Embodiment

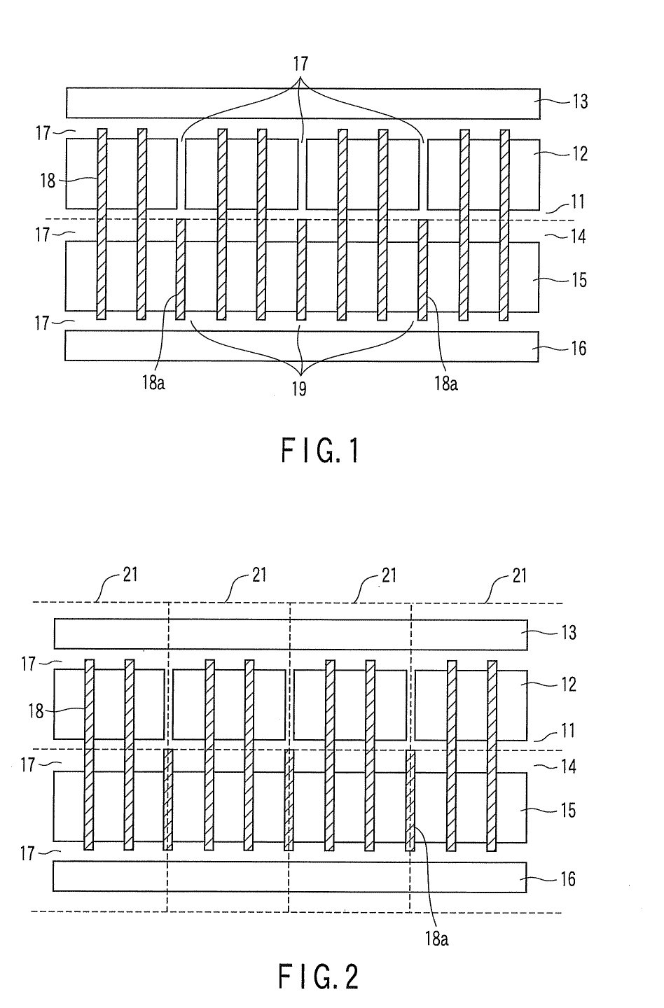

FIG. 1 shows a pattern layout according to a first embodiment. A semiconductor substrate has an N-well region 11 formed therein, in which the active regions 12 of P-channel transistors and an N-sub region 13 for making contact with an N-well lead-out electrode are formed. The semiconductor substrate further has a P-well region 14 formed therein, in which the active regions 15 of N-channel transistors and a P-sub region 16 for making contact with a P-well lead-out electrode are formed. STI regions 17 are respectively formed between the N-well region 11 and P-well region 14, between the active regions 12 and N-sub region 13, and between the active regions 15 and P-sub region 16. The active regions 12, N-sub region 13, active regions 15, and P-sub region 16 respectively have strip-like patterns, such that the active regions 12 are adjacent to the active regions 15, and the strip-like patterns extend parallel to each other as a whole.

Further, in this embodiment, STI regions 17 are respectively formed at positions at which the active regions 12 are divided into a plurality of unit portions in the longitudinal direction, e.g., each for every two P-channel transistors. Each pair of a P-channel transistor and an N-channel transistor in the active regions 12 and active regions 15 adjacent to each other are provided with a common gate electrode 18, which is formed through a gate insulating film and extends across the regions 12 and 15.

Further, in this embodiment, dummy gate electrodes 18a for gate isolation are respectively formed at positions at which the active regions 15 are divided into a plurality of unit portions in the longitudinal direction, e.g., each for every two N-channel transistors. The dummy gate electrodes 18a provide gate isolation regions 19 using normally-off transistors.

According to the arrangement described above, the P-channel transistors are provided with STI structures each for every two P-channel transistors. Since the STI regions 17 are present on both side of each of the active regions 12 in the channel-length direction, the channel region of each of the P-channel transistors receives STI stress in a compression direction from a direction perpendicular to the channel region (channel-length direction), and the P-channel transistors are thereby improved in characteristic.

On the other hand, the N-channel transistors are provided with gate isolation structures each for every two gate electrodes 18. Since the active regions 15 are thus arranged, each channel region receives no STI stress in a compression direction from a direction perpendicular to the channel region, i.e., receives no compression stress, and the N-channel transistors are thereby prevented from suffering degraded performance.

### Example of First Embodiment

FIG. 2 is a view showing a gate array comprising a number of basic cells 21 arrayed in rows and columns. Each of the basic cells 21 is formed of the P-channel transistors in one unit portion of active regions 12 and the N-channel transistors in one unit portion of active regions 15 adjacent to each other in FIG. 1.

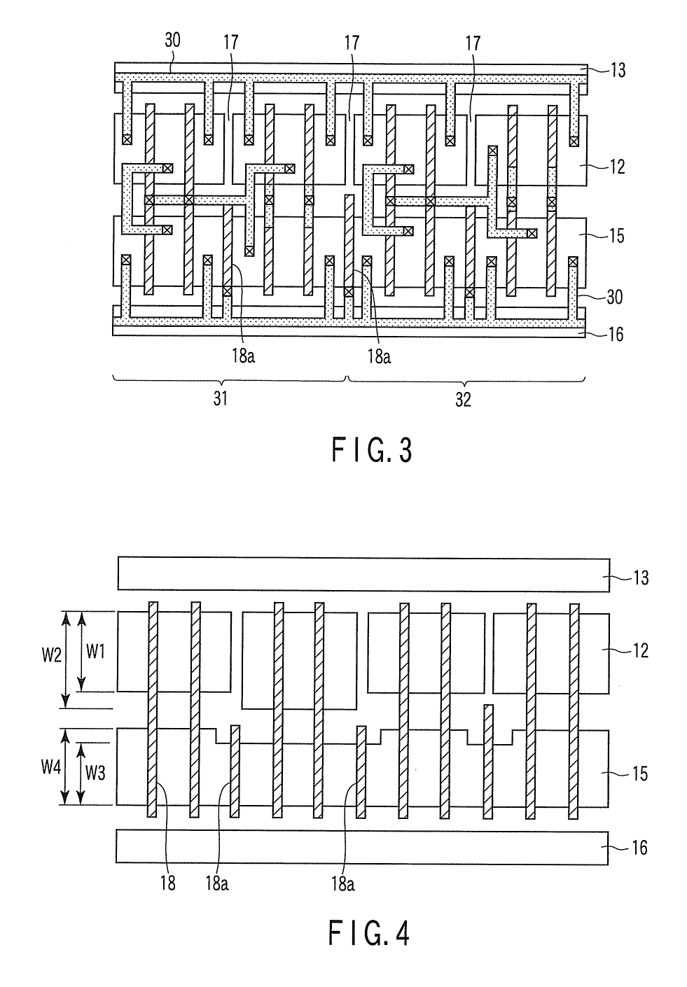

FIG. 3 is a view showing the pattern layout of a device where a two-input AND gate circuit 31 and a two-input OR gate circuit 32, which are of the CMOS type, are structured as an example of the gate array.

Each set of the two-input AND gate circuit 31 and two-input OR gate circuit 32 employs four P-channel transistors and four N-channel transistors. A P-sub region 16 is in contact with a metal interconnection line 30, which is in contact with dummy gate electrodes 18a for normally-off transistors in active regions 15, wherein a ground potential is applied to the dummy gate electrodes 18a. The active regions 15 are isolated from each other by gate isolation regions 19. On the other hand, unit portions formed of active regions 12 are isolated from each other by STI regions 17, and thus no gate isolation structures are formed here.

With this arrangement, the respective P-channel transistors receive stress in a compression direction from the STI regions 17, and the transistors are thereby improved in characteristic. On the other hand, since no STI structures are used to isolate unit portions formed of the active regions 15, the channel regions of the N-channel transistors receive no compression stress from STI regions, and the N-channel transistors is thereby prevented from suffering degraded performance. Consequently, it is possible to improve the two-input AND gate circuit 31 and two-input OR gate circuit 32 in characteristic.

### First Modification of First Embodiment

FIG. 4 is a view showing a first modification. In the pattern layout shown in FIG. 4, partly different transistor sizes are used in unit portions formed of the active regions 12 of P-channel transistors. Specifically, a part of the unit portions formed of the active regions 12 has a width W2 (the channel width of a P-channel transistor) greater than the width W1 of the other unit portions. On the other hand, a part of the unit portions formed of the active regions 15 of the N-channel transistors has a width W3 (the channel width of an N-channel transistor) smaller than the width W4 of the other unit portions. Further, the length (gate length) of gate electrodes 18a for normally-off transistors is set to be shorter in the active regions 15 of the N-channel transistors. In this case, it is possible to further improve the characteristic of the P-channel transistor having the greater channel width W2. Such a semiconductor integrated circuit device is suitable for a case where a standard cell is formed of a unit portion of a P-channel transistor and a unit portion of an N-channel transistor.

In reverse, where the characteristic of an N-channel transistor needs to be further improved, the width of a unit portion as a part of the active regions 15 of the N-channel transistors is set to be greater than the width of the other unit portions. Further, in accordance with this modification, the width of a unit portion as a part of the active regions 12 of the P-channel transistors is set to be smaller than the width of the other unit portions.

### Second Modification of First Embodiment

In the semiconductor integrated circuit devices shown in FIGS. 1 to 4, the active regions 12 of two P-channel transistors form one unit portion, and the active regions 15 of two N-channel transistors form one unit portion. However, this is not limiting. For example, a basic cell may be formed of unit portions respectively comprising one P-channel transistor and one N-channel transistor. Alternatively, a basic cell may be formed of unit portions respectively comprising three or more P-channel transistors and three or more N-channel transistors.

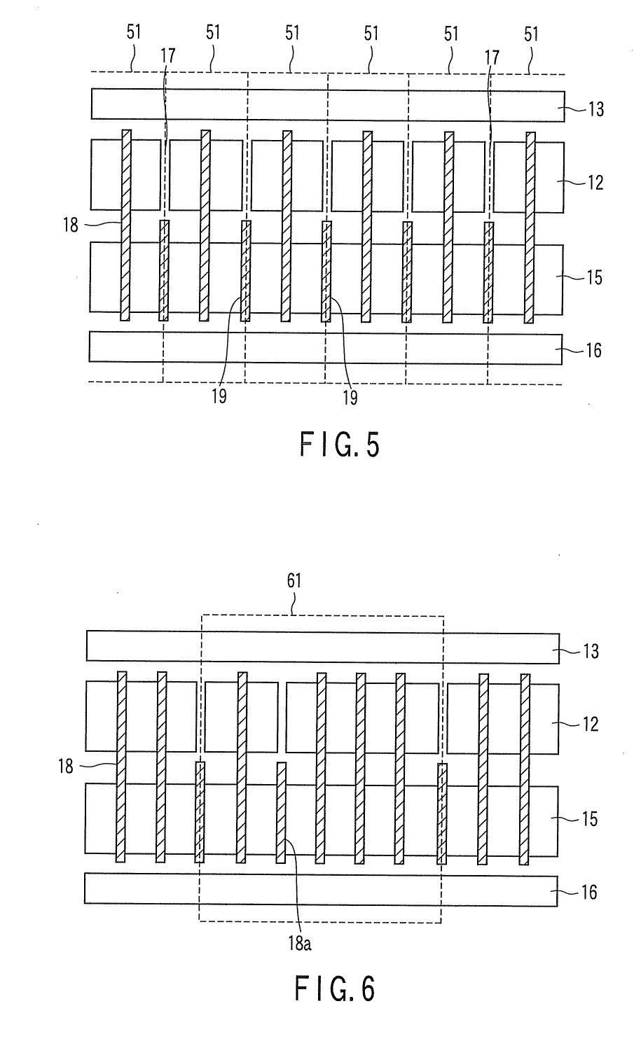

FIG. 5 is a view showing the pattern layout of a gate array according to a second modification of the first embodiment. The pattern layout shown in FIG. 5 differs from the pattern layouts shown in FIGS. 1 to 4, as follows. Specifically, STI regions 17 are respectively formed at positions at which the active regions 12 of P-channel transistors are divided into a plurality of unit portions in the longitudinal direction, each for every one P-channel transistor. Further, gate isolation regions 19 are respectively formed at positions at which the active regions 15 of N-channel transistors are divided into a plurality of unit portions in the longitudinal direction, each for every one N-channel transistor. Each pair of a P-channel transistor and an N-channel transistor in the active regions 12 and active regions 15 adjacent to each other are used to form one basic cell of the gate array, such as a CMOS inverter circuit 51. The gate array comprising a number of basic cells 51 arrayed in rows and columns.

### Second Embodiment

In the pattern layouts described in the first embodiment, one unit portion from the active regions 12 of P-channel transistors and one unit portion from the active regions 15 of N-channel transistors are used to form one basic cell of a gate array. However, this is not limiting.

FIG. 6 is a view showing a pattern layout according to a second embodiment. In FIG. 6, active regions 12 and active regions 15 are divided into a plurality of unit portions, each for irregular number of transistors, such that one unit portion is formed of one transistor, two transistors, or more. Further, a plurality of, e.g., two unit portions adjacent to each other are combined to define each cell grid, so that standard cells 61 having various cell grid sizes are prepared.

In a semiconductor integrated circuit device using standard cells 61 or basic cells 51 prepared as described above, gate isolation structures are used to provide device isolation on the transistors of one of the N-channel type and the P-channel type, while STI structures are used to provide device isolation on the transistors of the other of the N-channel type and the P-channel type, thereby improving transistor performance in a gate array or the like.

According to the embodiments described above, there is provided a semiconductor integrated circuit device comprising a CMOS circuit, which includes N-channel transistors and P-channel transistors, wherein a region isolated by a gate isolation structure contains one or more transistors, and a region isolated by an STI structure contains one or more transistors. One region isolated by an STI structure contains one P-channel transistor used for an inverter circuit or two P-channel transistors used for an AND gate circuit or OR gate circuit. Where the number of transistors contained in one region isolated by an STI structure can be one or more, i.e., the number is changeable, the following advantages are obtained. Specifically, for example, in the case of a CMOS inverter, only one P-channel transistor and one N-channel transistor are used. In this case, unit portions for P-channel transistors are formed each in the minimum size such that one unit portion is formed of one transistor. Further, these unit portions are arranged to receive STI stress. Consequently, it is possible to improve the transistors in performance while decreasing the cell size. On the other hand, for example, in the case of a two-input NAND gate circuit of the CMOS type, two P-channel transistors and two N-channel transistors are required. In this case, each unit portion is formed of two transistors and is arranged to receive STI stress from opposite sides. Consequently, it is possible to improve the transistors in performance while decreasing the cell size.

### Third Embodiment

In the embodiments and modifications described above, P-channel transistors are arranged to receive STI stress in the compression direction at their channel regions, so that the transistors are improved in characteristic. Further, N-channel transistors are provided with gate isolation structures to receive no compression stress from STI at their channel regions, so that the transistors are prevented from suffering degraded performance.

However, depending on the material and/or manufacturing method used in a semiconductor process, an arrangement opposite to that described above may be effective to improve transistors in characteristic. In this case, P-channel transistors are provided with gate isolation structures, while N-channel transistors are provided with STI structures.

### Fourth Embodiment

In the fourth embodiment, P-channel transistors provided with device isolation by STI structures are combined with P-channel transistors provided with device isolation by gate isolation structures. Further, N-channel transistors provided with device isolation by gate isolation structures are combined with N-channel transistors provided with device isolation by STI structures. These combinations are used to form a delay cell region in which the delay characteristic of transistors is controlled to increase the delay. In this case, a delay cell for adjusting clock skew can be formed to have a delay characteristic with a greater delay, so number of cells used in a delay circuit is decreased as a whole and the cell size can be thereby smaller.

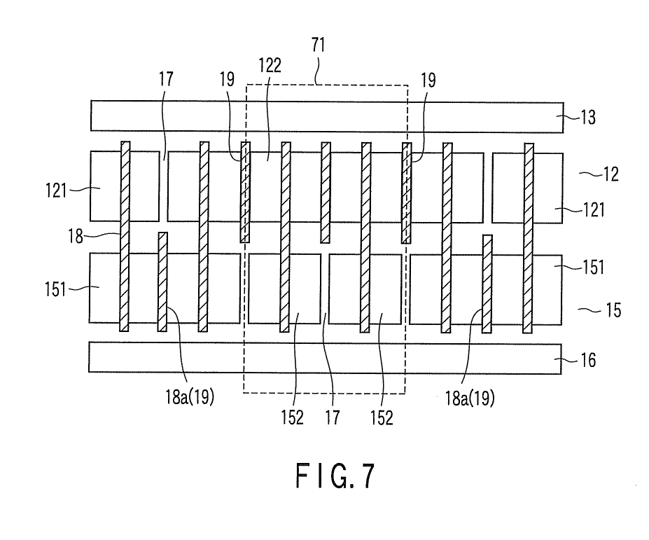

FIG. 7 is a view showing a semiconductor integrated circuit device according to a fourth embodiment. As shown in FIG. 7, first active regions 121 of P-channel transistors are provided with device isolation by STI regions 17. Second active regions 122 of P-channel transistors are provided with device isolation by gate isolation regions 19. First active regions 151 of N-channel transistors are provided with device isolation by gate isolation regions 19. Second active regions 152 of N-channel transistors are provided with device isolation by STI regions 17. One second active region 122 and two second active regions 152 are used to form a delay cell region 71.

With this arrangement, the channel regions in the first active regions 121 of P-channel transistors receive stress in a compression direction due to STI stress, and the transistors are thereby improved in characteristic. Further, the channel regions in the first active regions 151 of N-channel transistors receive no compression stress due to STI, and the transistors are thereby prevented from suffering degraded performance.

On the other hand, in the delay cell region 71, the channel regions in the second active regions 152 receive STI stress, and the transistors thereby suffer degraded performance. Further, the channel regions in the second active region 122 receive no compression stress from STI, the transistors are degraded in characteristic as compared to a state supplied with STI stress. Accordingly, where a delay cell is formed by use of the delay cell region 71, the delay time can be greater than that obtained by a delay cell formed of normal regions, i.e., the first active region 121 and first active region 151. Consequently, a delay cell for handling clock skew can be formed to have a small cell size and a large delay time.

In this embodiment, the transistor channel width in the active regions of P-channel transistors and the transistor channel width in the active regions of N-channel transistors may be adjusted, as needed, as described in a modification of the first embodiment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor integrated circuit device comprising a CMOS circuit that includes
a plurality of N-channel transistors provided with device isolation by one of a gate isolation structure and a shallow trench isolation structure, and
a plurality of P-channel transistors provided with device isolation by the other of the gate isolation structure and the shallow trench isolation structure.

2. The semiconductor integrated circuit device according to claim 1, further comprising:
a P-well region in which the plurality of N-channel transistors are formed; and
an N-well region in which the plurality of P-channel transistors are formed.

3. The semiconductor integrated circuit device according to claim 1, wherein the plurality of N-channel transistors are provided with device isolation by the gate isolation structure, and the plurality of P-channel transistors are provided with device isolation by the shallow trench isolation structure.

4. The semiconductor integrated circuit device according to claim 1, wherein the gate isolation structure includes a dummy gate electrode.

5. The semiconductor integrated circuit device according to claim 1, wherein the CMOS circuit includes a plurality of basic cells that form a standard cell.

6. The semiconductor integrated circuit device according to claim 1, wherein the CMOS circuit includes a plurality of basic cells that form a gate array.

7. The semiconductor integrated circuit device according to claim 1, wherein the plurality of N-channel transistors have the same channel width as each other, and the plurality of P-channel transistors have the same channel width as each other.

8. The semiconductor integrated circuit device according to claim 1, wherein the plurality of N-channel transistors include a plurality of first N-channel transistors having a first channel width and a plurality of second N-channel transistors having a second channel width different from the first channel width, and
the plurality of P-channel transistors include a plurality of first P-channel transistors having a third channel width and a plurality of second P-channel transistors having a fourth channel width different from the third channel width.

9. A semiconductor integrated circuit device comprising a delay circuit that includes
a plurality of P-channel transistors provided with device isolation by a gate isolation structure, and
a plurality of N-channel transistors provided with device isolation by a shallow trench isolation structure.

10. The semiconductor integrated circuit device according to claim 9, wherein the gate isolation structure includes a dummy gate electrode.

11. The semiconductor integrated circuit device according to claim 9, further comprising:
an N-well region in which the plurality of P-channel transistors are formed; and
a P-well region in which the plurality of N-channel transistors are formed.

12. A semiconductor integrated circuit device comprising:
a first region that includes a plurality of first channel transistors provided with device isolation by a shallow trench isolation structure; and
a second region that includes a plurality of second channel transistors provided with device isolation by a gate isolation structure.

13. The semiconductor integrated circuit device according to claim 12, further comprising:
a first-well region in which the plurality of first channel transistors is formed; and
a second-well region in which the plurality of second channel transistors is formed.

14. The semiconductor integrated circuit device according to claim 12, wherein the first channel transistors are N-channel transistors, and the second channel transistors are P-channel transistors.

15. The semiconductor integrated circuit device according to claim 12, wherein the first channel transistors are P-channel transistors, and the second channel transistors are N-channel transistors.

16. The semiconductor integrated circuit device according to claim 12, wherein the gate isolation structure includes a dummy gate electrode.

17. The semiconductor integrated circuit device according to claim 12, wherein the plurality of first channel transistors and the plurality of second channel transistors form a plurality of basic cells of a standard cell.

18. The semiconductor integrated circuit device according to claim 12, wherein the plurality of first channel transistors and the plurality of second channel transistors form a plurality of basic cells of a gate array.

19. The semiconductor integrated circuit device according to claim 12, wherein the plurality of first channel transistors have the same channel width as each other, and the plurality of second channel transistors have the same channel width as each other.

20. The semiconductor integrated circuit device according to claim 12, wherein the plurality of first channel transistors include a plurality of first transistors having a first channel width and a plurality of second transistors having a second channel width different from the first channel width, and
the plurality of second channel transistors include a plurality of third transistors having a third channel width and a plurality of fourth transistors having a fourth channel width different from the third channel width.
